(19) United States
(12) Patent Application Publication
(10) Pub. No.: US 2015/0319888 A1
(43) Pub. Date: Nov. 5, 2015

(54) CONTAINER DATA CENTER

(71) Applicant: HON HAI PRECISION INDUSTRY CO., LTD., New Taipei (TW)

(72) Inventor: CHING-BAI HWANG, New Taipei (TW)

(21) Appl. No.: 14/525,884

(22) Filed: Oct. 28, 2014

(30) Foreign Application Priority Data
Apr. 30, 2014 (TW) 103115496

(51) Int. Cl. H05K 7/20

(52) U.S. Cl. CPC H05K 7/20736

(57) ABSTRACT

A container data center includes a container and a row of server cabinets received in the container. The container includes a front wall defining a plurality of air inlets and a rear wall defining a plurality of air outlets. Each server cabinet is adjoined with an inner surface of the rear wall. Cooling air enters into the container from the air inlets of the front wall and flows through the server cabinets, and is directly exhausted through the air outlets of the rear wall.

### FIELD

The subject matter herein generally relates to data centers, and more particularly to a container data center.

### BACKGROUND

With increasing use of on-line applications, the need for computer data centers has increased rapidly. Data centers are centralized computing facilities that include many servers, often arranged on server racks or shelves, and one rack or shelf with some servers can be considered a server system. During operation, server systems generate heat in the data centers, and the heat can be dissipated by using air conditioners.

### BRIEF DESCRIPTION OF THE DRAWINGS

Implementations of the present technology will now be described, by way of example only, with reference to the attached figures.

FIG. 1 is a partial cutaway, isometric view of an embodiment of a container data center.

FIG. 2 is a cross-sectional view of FIG. 1, taken along line of II-II, showing the container data center in use.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently coupled or releasably coupled. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

The present disclosure is described in relation to a container data center.

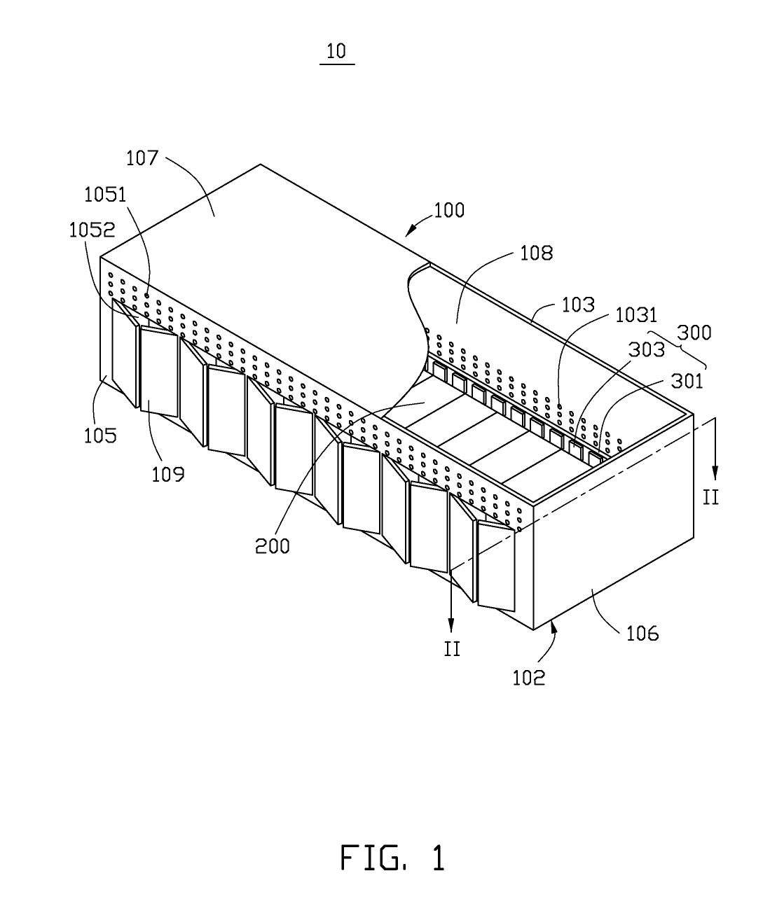

FIG. 1 illustrates an isometric view of a container data center 10. The container data center 10 comprises a container 100, a row of server cabinets 200 received in the container 100, and a heat dissipation apparatus 300.

The container 100 comprises a substantially rectangular bottom wall 102, a front wall 103 substantially perpendicularly extending up from a front side of the bottom wall 102, a rear wall 105 substantially perpendicularly extending up from a rear side of the bottom wall 102 opposite to the front wall 103, two opposite end walls 106 substantially perpendicularly extending up from two opposite ends of the bottom wall 102 and connecting between the front wall 103 and the rear wall 105, and a top wall 107. The front wall 103 defines a plurality of air inlets 1031. The rear wall 105 defines a plurality of air outlets 1051. The rear wall 105 defines a plurality of openings 1052 facing the server cabinets 200 for expediently operating the server cabinets 200. A plurality of shielding doors 109 can be rotatably coupled to the rear wall 105 for covering the corresponding openings 1052.

The row of server cabinets 200 are supported on the bottom wall 102, and located along a lengthwise direction of the bottom wall 102. A rear surface of each server cabinet 200 engages with an inner surface of the rear wall 105, and is opposite to the corresponding air outlets 1051. The server cabinets 200 and the front wall 103 cooperatively bound a cooling channel 108.

The heat dissipation apparatus 300 comprises a filter 301 mounted on an inner surface of the front wall 103 opposite to the air inlets 1031 and a plurality of fans 303 installed to the filter 301.

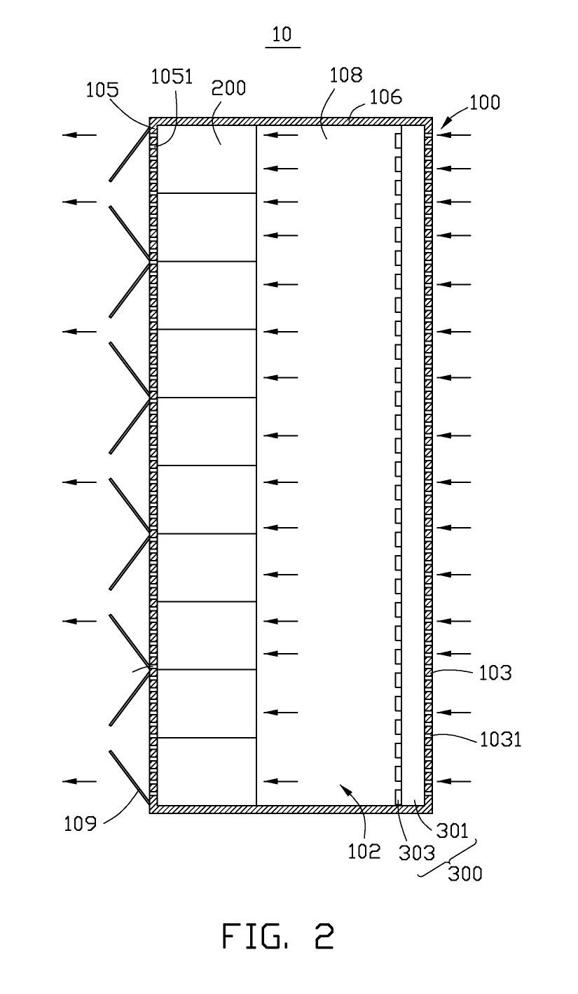

FIG. 2 illustrates the container data center 10 in use, the fans 303 drive cool air to flow through the air inlets 1031 and the filter 301, and enter into the cooling channel 108. The cool air passes through the server cabinets 200 and becomes heated air by heat exchanging with the server cabinets 200. The heated air can directly flow out the container 100 through the air outlets 1051.

The server cabinets 200 are engaged with an inner surface of the rear wall 105, so the route of the heated air is shorten, and the heated air is directly exhausted through the air outlets 1051 of the rear wall 105.

Even though numerous characteristics and advantages of the embodiments have been set forth in the foregoing description, together with details of the structure and function of the embodiments, the present disclosure is illustrative only, and changes may be made in detail, including in the matters of shape, size, and arrangement of parts within the principles of the embodiments to the full extent indicated by the broad general meaning of the terms in which the appended claims are expressed.

What is claimed is:

1. A container data center comprising:
a container comprising a front wall defining a plurality of air inlets and a rear wall defining a plurality of air outlets; and
a row of server cabinets configured to be received in the container; wherein each server cabinet is configured to adjoin with an inner surface of the rear wall, cooling air is configured to enter into the container from the air inlets of the front wall and flow through the server cabinets, and is directly exhausted through the air outlets of the rear wall.

2. The container data center of claim 1, wherein the server cabinets and the front wall cooperatively bound a cooling channel, the cooling air enters into the cooling channel from the air inlets of the front wall.

3. The container data center of claim 2, further comprising a heat dissipation apparatus, wherein the heat dissipation apparatus comprises a plurality of fans configured to be received in the container for driving the cool air to flow through the air inlets and enter in the cooling channel.

4. The container data center of claim 3, wherein the heat dissipation apparatus further comprises a filter configured to be mounted to the front wall opposite to the air inlets.

5. The container data center of claim 4, wherein the filter is configured to be mounted to an inner surface of the front wall, the fans are configured to be mounted to the filter.

6. The container data center of claim 1, wherein the rear wall is configured to define a plurality of openings opposite to the server cabinets.

7. The container data center of claim 6, wherein the container further comprises a plurality of shielding doors configured to be coupled to the rear wall, the shielding doors are configured to cover the openings.

8. A container data center comprising:
a container comprising a front wall defining a plurality of air inlets and a rear wall defining a plurality of air outlets; and
a row of server cabinets configured to be received in the container; wherein each server cabinet is configured to engage with an inner surface of the rear wall, cooling air is configured to enter into the container from the air inlets of the front wall and flow through the server cabinets, and is directly exhausted through the air outlets of the rear wall.

9. A data center structure comprising:
a container comprising a front wall defining a plurality of air inlets and a rear wall defining a plurality of air outlets;
server cabinets provided within the container; the server cabinets being mechanically coupled to an inner surface of the rear wall to directly exhaust heated air through the plurality of air outlets; and
a cooling channel defined between the front wall and the server cabinets, the cooling channel being configured to guide cooled air from the plurality of air inlets through the server cabinets, the server cabinets producing the heated air.

10. The data center structure of claim 9, further comprising a heat dissipation apparatus, wherein the heat dissipation apparatus comprises a plurality of fans configured to be received in the container for driving the cool air to flow through the air inlets and enter in the cooling channel.

11. The data center structure of claim 10, wherein the heat dissipation apparatus further comprises a filter configured to be mounted to the front wall opposite to the air inlets.

12. The data center structure of claim 11, wherein the filter is configured to be mounted to an inner surface of the front wall, the fans are configured to be mounted to the filter.

13. The data center structure of claim 9, wherein the rear wall is configured to define a plurality of openings opposite to the server cabinets, the container further comprises a plurality of shielding doors configured to be coupled to the rear wall, the shielding doors are configured to cover the openings.
